(19) United States
(12) Patent Application Publication
(10) Pub. No.: US 2018/0030615 A1
(43) Pub. Date: Feb. 1, 2018

(54) METHODS FOR PRODUCING SINGLE CRYSTAL SILICON INGOTS WITH REDUCED SEED END OXYGEN

(71) Applicant: SunEdison Semiconductor Limited (UEN201334164H), Singapore (SG)

(72) Inventors: Doh Hyung Kwon, Cheonan (KR); Hyung Min Lee, Cheonan (KR); Jae Woo Ryu, Chesterfield, MO (US); Young Jung Lee, Cheonan (KR); Jong Hak Lee, Cheonan (KR); Jun Hwan Ji, Cheonan (KR); Byung Chun Kim, Cheonan (KR)

(21) Appl. No.: 15/662,844

(22) Filed: Jul. 28, 2017

Related U.S. Application Data
(60) Provisional application No. 62/367,732, filed on Jul. 28, 2016.

(51) Int. Cl. C30B 15/20; C30B 29/06; C30B 15/14; C30B 15/30; C30B 15/10

(52) U.S. Cl. CPC C30B 15/20; C30B 15/30; C30B 15/10; C30B 15/14; C30B 29/06

(57) ABSTRACT

Methods for producing single crystal silicon ingots with a reduced oxygen content toward the seed end of the ingot are disclosed. The methods may involve controlling growth conditions during crown formation and, in some embodiments, controlling the rate of crucible rotation during crown rotation to increase the time the crucible is rotated at or below a threshold value during crown growth.

### CROSS-REFERENCE TO RELATED APPLICATION

This application claims the benefit of U.S. Provisional Patent Application No. 62/367,732, filed Jul. 28, 2016, which is incorporated herein by reference in its entirety.

### FIELD OF THE DISCLOSURE

The field of the disclosure relates to methods for producing single crystal silicon ingots and, in particular, methods for producing ingots with a reduced oxygen content toward the seed end of the ingot by controlling the rate of rotation during crown growth.

### BACKGROUND

Single crystal silicon, which is the starting material for most processes for the fabrication of semiconductor electronic components, is commonly prepared by the so-called Czochralski (“Cz”) method. Referring now to FIG. 1, in this method polycrystalline silicon (“polysilicon”) is charged to a crucible and melted, a seed crystal 6 is brought into contact with the molten silicon and a single crystal ingot 8 is grown by slow extraction. After formation of a neck 9 is complete, the diameter of the crystal is enlarged, typically by decreasing the pulling rate and/or the melt temperature, to form a crown or taper portion 12, also referred to in some instances as the seed-cone, until the desired or target diameter is reached. Once the target diameter is reached, formation of the shoulder 15 occurs, the taper being “rolled” to begin growth of the constant diameter portion 18, or cylindrical main body or simply “body”, of the crystal by increasing the pull rate. The main body 18 of the crystal has an approximately constant diameter and is grown by controlling the pull rate and the melt temperature while compensating for the decreasing melt level. Near the end of the growth process but before the crucible is emptied of molten silicon, the crystal diameter is typically reduced gradually to form an end opposite the taper, commonly referred to as the end-cone 21 (FIG. 2). The end-cone 21 is typically formed by increasing the crystal pull rate and heat supplied to the crucible. When the diameter becomes small enough, the single crystal ingot is then separated from the melt. The ingot 9 has a central longitudinal axis A that extends through the neck 9 and a terminal end 25 of the ingot.

Oxygen is typically introduced into the silicon melt from the crucible, which is typically made of quartz (SiO₂). During the solidification process, oxygen from the melt is incorporated into silicon crystal ingot. The oxygen (which may be referred to as interstitial oxygen or simply “Oi”) can be beneficial to the silicon ingot and the wafers and devices made from that ingot, however it may also be detrimental and in some cases may also contribute to the formation of various defects in wafers produced from the ingots, reducing the yield of semiconductor devices fabricated using those wafers. For example, insulated-gate bipolar transistors (IGBTs), high quality radio-frequency (RF), high resistivity silicon on insulator (HR-SOI), and charge trap layer SOI (CTL-SOI) applications typically require a low oxygen concentration in order to achieve high resistivity and to avoid formation of P-N junctions.

The rate at which oxygen is taken up in the ingot varies over the length of the ingot with the seed-end of the constant diameter portion of the ingot typically having higher oxygen concentrations relative to the remainder of the ingot. FIG. 3 shows the oxygen concentration (as measured by ASTM F121, '79) as a function of the solidification fraction of the ingot. Initially, the concentration of oxygen in the ingot is relatively high because the silicon melt level is at its highest level which increases the contact surface between the crucible inner wall and the silicon melt. As the crystal grows, the melt level decreases which reduces the melt-crucible interface area. The rate at which oxygen is taken up by the ingot and evaporated from the melt exceeds the rate at which oxygen is introduced from the crucible which causes the oxygen concentration in the melt to decrease. This in turn lowers the concentration of oxygen in the ingot as the ingot is grown. With reference to FIG. 4, as the crucible is raised, heater power is increased to compensate for heat loss through the smaller melt volume which causes the oxygen concentration in the ingot near the end-cone 21 to increase. As the melt level reaches the round crucible bottom and decreased in radius, the evaporation surface area decreases which also causes the oxygen concentration in the ingot near the end-cone 21 to increase.

Wafers sliced from the ingot that have an oxygen concentration that does not meet product specifications (e.g., 4.4 ppma oxygen or less) must be used for other purposes which reduces the overall value of the ingot. As low oxygen concentration is difficult to achieve toward the seed end of the ingot, wafers sliced from the body nearest the seed-end often do not meet the product specification. This “non-prime” region of the body may extend to 10% of the length of the body or more.

A need exists for methods for preparing single crystal silicon ingots in which the oxygen content in a region of the body of the ingot nearest the seed-end is reduced compared to conventional methods to allow a larger portion of the ingot to meet stringent oxygen specifications for use in various devices such as insulated-gate bipolar transistors (IGBTs), high quality radio-frequency (RF), high resistivity silicon on insulator (HR-SOI), and charge trap layer SOI (CTL-SOI).

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for producing a single crystal silicon ingot from a silicon melt held within a crucible. The ingot has a constant diameter portion, a neck portion, a crown portion disposed between the neck portion and the constant diameter portion and tapering radially outward toward the constant diameter portion, and a terminal end. The method includes contacting the melt with a seed crystal to initiate crystal growth. The seed crystal is pulled away from the melt to form the neck portion of the ingot. A crown portion of the ingot is formed with the crucible rotating while forming the crown at a crucible rotation rate. The constant diameter portion of the ingot is formed after the crown portion reaches a target diameter. The constant diameter portion has a seed region that extends from the crown portion and toward the terminal end of the ingot. The crucible rotation rate during formation of the crown portion is controlled to reduce the oxygen content in the seed region of the constant diameter portion of the ingot.

Another aspect of the present disclosure is directed to a single crystal silicon ingot grown by a Czochralski method. The ingot includes a constant diameter portion, a neck portion, and a crown portion disposed between the neck portion and the constant diameter portion and tapering radially outward toward the constant diameter portion. The ingot has a terminal end. The constant diameter portion has a seed region that extends from the crown portion and toward the terminal end of the ingot. The seed region has a length of about 150 mm or less. A portion of the seed region has an oxygen concentration of about 4.4 ppma or less.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic side view of the top portion of a single crystal silicon ingot;

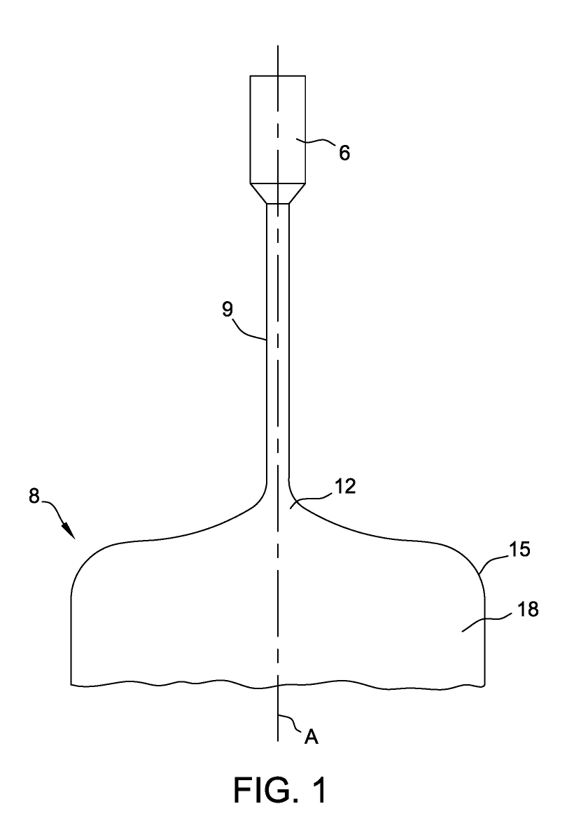

FIG. 2 is a schematic side view of the ingot;

FIG. 3 is a graph showing the oxygen concentration as it varies with the solidified fraction in conventional crystal pulling methods;

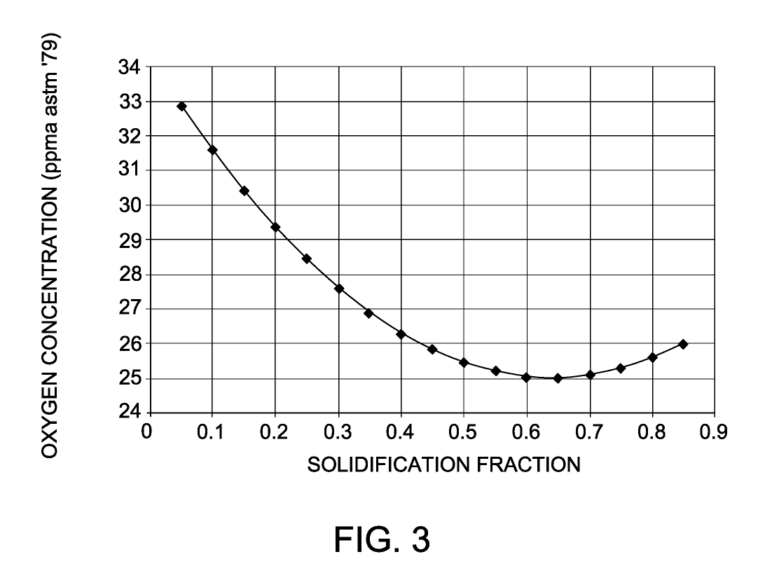

FIG. 4 is a schematic showing changes in the heat flux as a crucible is raised during ingot growth;

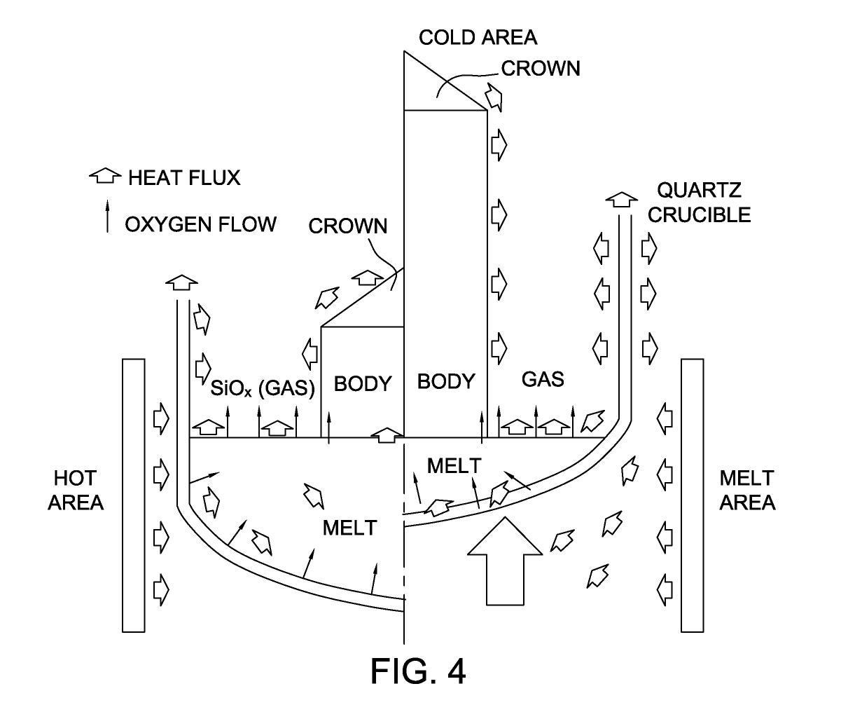

FIG. 5 is a schematic side view of a pulling apparatus for forming a single crystal silicon ingot;

FIG. 6 is a graph showing the normalized crucible rotation as a function of normalized crown length for ingots grown in accordance with Example 1;

FIG. 7 is a graph showing the normalized heater power as a function of crown diameter for ingots grown in accordance with Example 1;

FIG. 8 is a graph showing the oxygen concentration and non-prime portion as a function of solidification fraction for 200 mm and 300 ingots;

FIG. 9 is a graph showing the normalized crucible rotation as a function of normalized crown diameter for ingots grown in accordance with Example 1;

FIG. 10 is a graph showing the crown shape for ingots grown in accordance with Example 1;

FIG. 11 is a graph showing the oxygen concentration as a function of normalized crystal length for ingots prepared in accordance with Example 1 and by conventional methods;

FIG. 12 is a graph showing the oxygen concentration at 150 mm body length as a function of time at low crucible rotation rate;

FIG. 13 is a graph showing the oxygen concentration at 150 mm body length as a function of time at low crucible rotation rate for crown time and body time; and

FIG. 14 is a bar graph showing the oxygen concentration reduction for low crucible rotation during body growth and for crown growth.

Corresponding reference characters indicate corresponding parts throughout the drawings.

### DETAILED DESCRIPTION

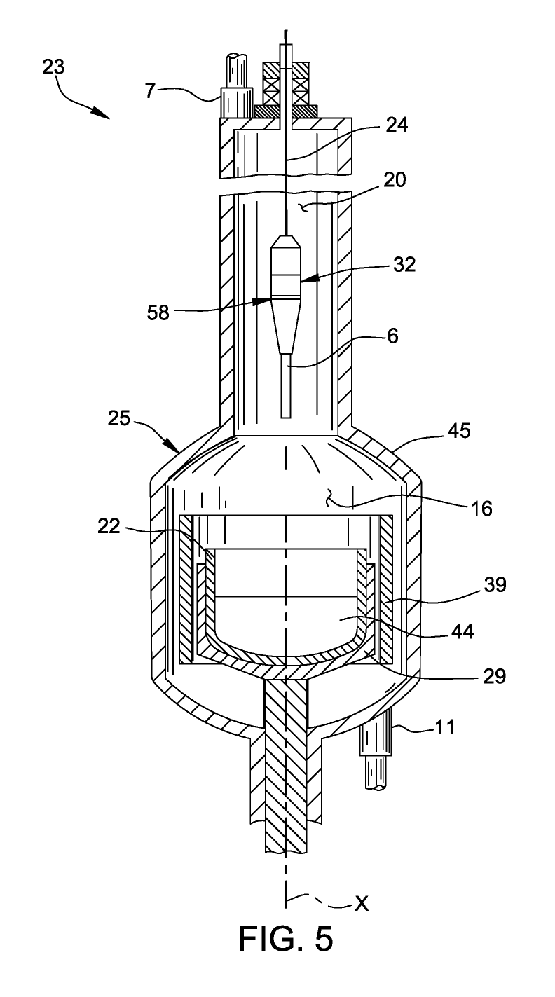

Provisions of the present disclosure relate to methods for forming a silicon ingot by controlling the crucible rotation rate during crown formation so as to reduce the oxygen content near the seed-end of the constant diameter portion of the ingot. In accordance with embodiments of the present disclosure and with reference to FIG. 5, the ingot is grown by the so-called Czochralski process in which the ingot is withdrawn from a silicon melt 44 held within a crucible 22 of a crystal puller 23.

The ingot puller 23 includes a housing 25 that defines a crystal growth chamber 16 and a pull chamber 20 having a smaller transverse dimension than the growth chamber. The growth chamber 16 has a generally dome shaped upper wall 45 transitioning from the growth chamber 16 to the narrowed pull chamber 20. The ingot puller 23 includes an inlet port 7 and an outlet port 11 which may be used to introduce and remove a process gas to and from the housing 25 during crystal growth.

The crucible 22 within the ingot puller 23 contains the silicon melt 44 from which a silicon ingot is drawn. The silicon melt 44 is obtained by melting polycrystalline silicon charged to the crucible 22. The crucible 22 is mounted on a turntable 29 for rotation of the crucible about a central longitudinal axis X of the ingot puller 23.

A heating system 39 (e.g., an electrical resistance heater 39) surrounds the crucible 22 for melting the silicon charge to produce the melt 44. The heater 39 may also extend below the crucible as shown in U.S. Pat. No. 8,317,919. The heater 39 is controlled by a control system (not shown) so that the temperature of the melt 44 is precisely controlled throughout the pulling process. Insulation (not shown) surrounding the heater 39 may reduce the amount of heat lost through the housing 25. The ingot puller 23 may also include a heat shield assembly (not shown) above the melt surface for shielding the ingot from the heat of the crucible 22 to increase the axial temperature gradient at the solid-melt interface.

A pulling mechanism (not shown) is attached to a pull wire 24 that extends down from the mechanism. The mechanism is capable of raising and lowering the pull wire 24. The ingot puller 23 may have a pull shaft rather than a wire, depending upon the type of puller. The pull wire 24 terminates in a pulling assembly 58 that includes a seed crystal chuck 32 which holds a seed crystal 6 used to grow the silicon ingot. In growing the ingot, the pulling mechanism lowers the seed crystal 6 until it contacts the surface of the silicon melt 44. Once the seed crystal 6 begins to melt, the pulling mechanism slowly raises the seed crystal up through the growth chamber 16 and pull chamber 20 to grow the monocrystalline ingot. The speed at which the pulling mechanism rotates the seed crystal 6 and the speed at which the pulling mechanism raises the seed crystal (i.e., the pull rate v) are controlled by the control system.

A process gas is introduced through the inlet port 7 into the housing 25 and is withdrawn from the outlet port 11. The process gas creates an atmosphere within the housing and the melt and atmosphere form a melt-gas interface. The outlet port 11 is in fluid communication with an exhaust system (not shown) of the ingot puller.

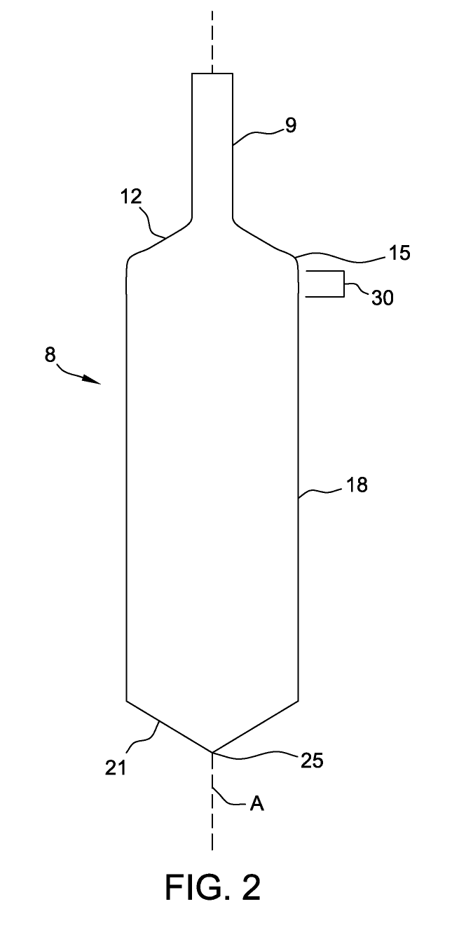

In accordance with embodiments of the present disclosure, the growth conditions during formation of the crown portion 12 (FIG. 2) of the ingot 8 are controlled to reduce the oxygen content in a region 30 (FIG. 2) of the body nearest the seed-end of the ingot (i.e., “near-seed” region 30 or simply “seed” region 30). As shown in FIG. 2, the seed region 30 of the constant diameter portion 18 of the ingot extends from the shoulder 15 of the crown and toward the terminal end 25 (i.e., end of end-cone 21). This seed region 30 of the constant diameter portion 18 in which oxygen is reduced may have a length of at least about 0.03%, at least about 0.1%, or at least about 1% of the length of the constant diameter portion or at least about 5%, less than about 15%, less than about 10%, less than about 8% or from about 3% to about 0.15% or from about 3% to about 10% the length of the constant diameter portion. In this regard, in some embodiments, the methods disclosed herein for reducing the oxygen content in the seed region 30 may also reduce the oxygen content outside of the seed region 30, i.e., further toward the terminal end 25.

In various embodiments, the constant diameter portion of the ingot may have a length from about 1500 mm to about 2500 mm or about 1700 mm to about 2100 mm. The crown portion 12 may have a length of from about 50 mm to about 120 mm and more typically from about 80 mm to about 110 mm.

The seed region 30 of the constant diameter portion 18 may correspond to a region of the ingot which is characterized by a relatively higher oxygen content in conventional manufacturing. A portion or all of the seed region 30 as produced conventionally may include an oxygen content that falls outside of present industry standards (e.g., greater than about 4.4 ppma).

In accordance with the present disclosure, the oxygen content of the seed region 30 of the constant dimeter portion 18 of the ingot may be reduced by controlling the crucible rotation (C/R) during formation of the crown portion 12 of the ingot. Control methods may involve reducing the rate of rotation of the crucible during crown formation earlier during crown formation and/or a reducing the rate of rotation at a faster rate to below a threshold value.

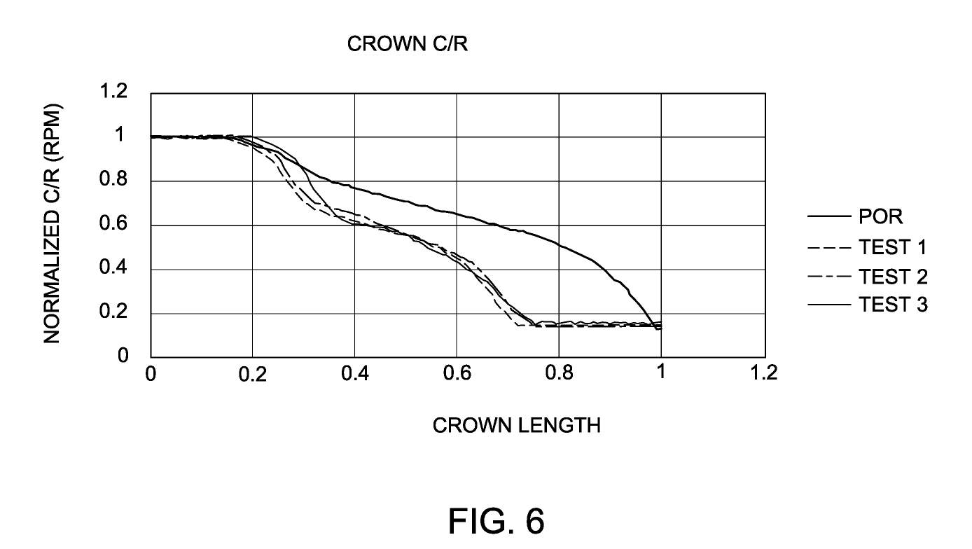

As shown in FIG. 6, the rate of rotation of the crucible is maintained at a relatively low rotation rate (e.g., to below a threshold level) during a relatively large portion of growth of the ingot crown. In some embodiments and as shown in FIG. 6, the rate of rotation during formation of at least about the last 10% of the length of the crown is maintained at about 20% or less of the rate of rotation during formation of the neck. In some embodiments, the rate of rotation during formation of at least about the last 20% of the length of the crown is maintained at about 20% or less of the rate of rotation during formation of the neck.

Generally, the rate of rotation of the crucible is constant during growth of the neck. In embodiments in which the rate of rotation varies during neck growth, the “rate of rotation during formation of the neck” refers to the rate at which the ingot begins to transition from neck growth to crown growth.

In some embodiments, the rate of rotation at which the crucible is maintained below for about the last 10% or even about the last 20% of the length of crown growth is about 3.0 RPM or lower. More preferably, the rate of rotation at which the crucible is maintained below for about the last 10% or even about the last 20% of the length of crown growth is about 2.5 RPM or lower as such a rotation rate allows a greater portion of the seed region 30 of the constant diameter portion 18 to be within stringent oxygen specifications (e.g., less than about 4.4 ppma). In some embodiments, a rotation rate of about 2.0 RPM or even lower (e.g., about 1.5 RPM) is used during growth of at least about the last 10% or even at least about the last 20% of the length of the crown.

The rotation rate of the crucible during crown growth may be maintained at or below the desired rotation rate threshold by increasing the rate at which the rotation is ramped down to the threshold. For example and with reference to FIG. 6, controlling the crucible rotation rate during formation of the crown portion may include reducing the rate of rotation by at least about 40% during formation of about the first 60% of the crown length relative to the rate of rotation of the crucible during formation of the neck. Preferably, the rate of rotation during crown growth is reduced by at least about 40% (relative to the rate of rotation of the crucible during formation of the neck) even sooner such as during formation of about the first 50% or even about the first 45% of the crown length.

In some embodiments and as shown in FIG. 6, controlling the crucible rotation rate during formation of the crown portion includes reducing the rate of rotation by at least about 50% or at least about 60% during formation of about the first 60% of the crown length relative to the rate of rotation of the crucible during formation of the neck. Alternatively or in addition and as shown in FIG. 6, crucible rotation ramp down may be achieved by reducing the rate of rotation by at least about 80% during formation of about the first 80% of the crown length relative to the rate of rotation of the crucible during formation of the neck.

By increasing ramp down as described, the crucible may be rotated at or below the threshold level (e.g., below about 2.5 RPM or even to about 2.0 RPM) for a longer period during crown formation without increasing the total length of time at which the crown is grown. For example, the crucible may be rotated at or below the threshold rotation rate for at least about 15 minutes, at least about 25 minutes or at least about 30 minutes prior to formation of the constant diameter portion of the ingot. By increasing the time at which the ingot is rotated at the relatively low rate (e.g., about 30 minutes at about 2.5 RPM or lower), the velocity of the melt within the crucible is lowered which is believed to decrease the convection flow of oxygen from the crucible wall and increases the evaporation of oxygen to the ingot puller atmosphere through the melt free surface which decreases uptake of oxygen into the ingot.

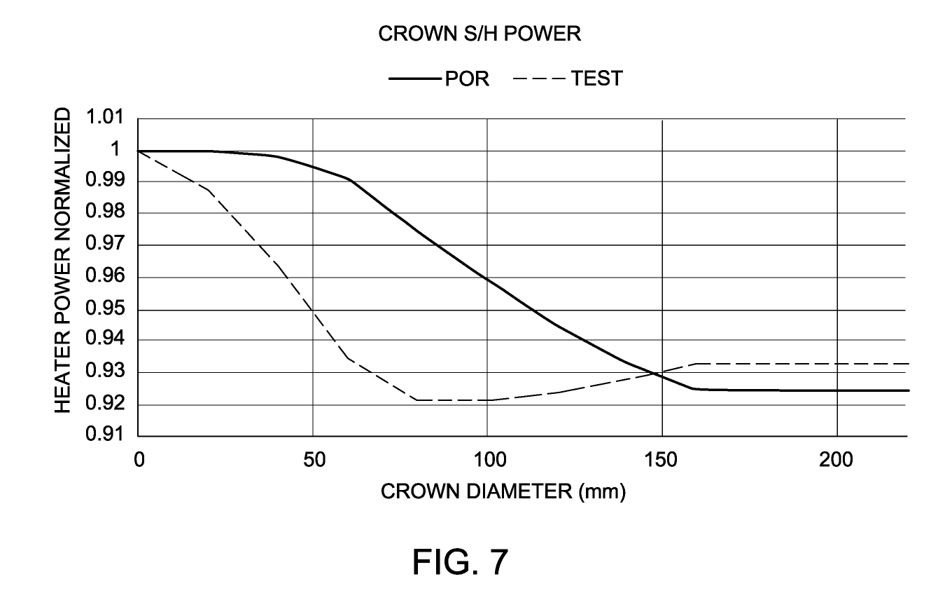

As the rate of rotation of the crucible is ramped down at the relatively quicker rate, the crystal-melt boundary increases in temperature relative to conventional methods which causes less solidification and increases the length of time for crown growth (i.e., lowers the rate at which the crown increases in diameter). To compensate for the increase in temperature and the increase in crown growth time, in some embodiments and as shown in FIG. 7, the power supplied to the heating system 39 is reduced relative to conventional methods during formation of the crown to compensate for reduced crown diameter caused by the lowered crucible rotation rate during crown growth. As shown in FIG. 7, the heater power is reduced by at least about 1%, at least about 2.5% or at least about 4% in about the first 25% of crown diameter growth (e.g., about 50 mm for 200 mm ingots as in FIG. 7 or about 75 mm for 300 mm ingots). Alternatively or in addition, heater power is reduced by at least about 5% or at least about 7.5% during growth of about the first 50% of the crown diameter.

By controlling the growth conditions as described, the portion of the seed region that has an oxygen concentration at or above 4.4 ppma is reduced (i.e., the non-prime portion of the body of the ingot is reduced). For example, at least about 5%, or even at least about 15%, at least about 25%, at least about 33%, at least about 50% or even at least about 75% of the seed region of the constant diameter portion of the ingot may have an oxygen concentration less than about 4.4 ppma. In some embodiments, the seed region of the constant diameter portion of the ingot (i.e., an ingot grown by the Czochralski method in which the ingot is pulled from a crucible such as a quartz crucible) has a length of about 150 mm or less and a portion of the seed region has an oxygen concentration of about 4.4 ppma or less or at least about 5% of the length or at least about 15%, at least about 25%, at least about 50%, or at least about 66% of the length of the seed region has an oxygen concentration of about 4.4 ppma or less (e.g., from about 5% to about 75% or from about 5% to about 50% of the length of the seed region has an oxygen concentration of about 4.4 ppma or less). In this regard, the oxygen concentrations referenced herein are determined in accordance with ASTM Standard F121 ('83), and SEMI MF1188, unless stated otherwise.

Provisions of the present disclosure also relate to a population of wafers sliced from the seed region of the constant diameter portion of the ingot. A portion of the wafers have an oxygen concentration of about 4.4 ppma or less. In some embodiments, at least about 5%, at least about 15%, at least about 25%, at least about 50% or at least about 66% of the wafers of the population have an oxygen concentration of about 4.4 ppma or less (e.g., from about 5% to about 75% or from about 5% to about 50% of the wafers have an oxygen concentration of about 4.4 ppma or less).

Generally, the crucible rotation control methods disclosed herein for reducing oxygen in the seed region of the constant diameter portion of the single crystal silicon ingot may be used for any diameter ingot such as ingots with a diameter of at least about 150 mm, at least about 200 mm or at least about 300 mm or about 450 mm.

Generally, the methods are applicable to systems in which the seed crystal is rotated in the same direction of the ingot (i.e., iso-rotation). The methods may also be applicable for counter-rotation or when the seed is not rotated. In embodiments in which iso-rotation is used, seed rotation rate may range from about 2 RPM to about 20 RPM. In some embodiments, the seed rotation may ramp up from about 6 RPM at the start of crown growth to about 12 RPM at the beginning of body growth. In alternative embodiments, the seed rotation is ramped up to about 12 RPM at the beginning of crown growth and maintained at about 12 RPM during growth of the crown. The ingot pull rate during crown growth may be variable (so as to control crown shape) or fixed (as in when crucible rotation and heater power control crown shape). Generally, the ingot pull rate during crown growth may range from about 0.4 mm/min to about 1.5 mm/min or from about 0.6 mm/min to about 0.8 mm/min.

After the desired crown diameter is achieved, the crystal pull rate is maintained to be relatively low to maintain low oxygen content as the constant diameter portion of the ingot is formed. In some embodiments, the crucible is rotated below about 3.0 RPM or below about 2.5 RPM when growth of the constant diameter portion of the ingot is initiated.

Compared to conventional methods for preparing ingots, the methods of the present disclosure have several advantages. By controlling the growth conditions of the crown, the oxygen concentration of the ingot in a seed region (e.g., first 150 mm of body) of the constant diameter portion of the ingot may be reduced. This allows more of the seed region to fall within more stringent customer specifications such as an oxygen concentration of less than about 4.4 ppma and reduces the “non-prime” portion of the body. In particular, control may involve increasing the amount of time (e.g., at least about 20 minutes and more preferably at least about 30 minutes) at which the crucible rotation rate is maintained below about 20% of the rotation rate during neck formation to reduce the non-prime portion of the body. By increasing the time at which the ingot is rotated at the relatively low rate (e.g., about 20 minutes or more at about 2.5 RPM or lower with about 30 minutes being preferred), the velocity of the melt within the crucible is lowered which decreases the convection flow of oxygen from the crucible wall and increases the evaporation of oxygen to the ingot puller atmosphere through the melt free surface which decreases uptake of oxygen into the ingot.

The amount of time at which the crucible rotation is maintained below the threshold amount may be increased without decreasing productivity (total growth time) by ramping down crucible rotation faster after crown growth is initiated (e.g., reducing the rate of rotation by at least about 40% during formation of about the first 60% of the crown length relative to the rate of rotation of the crucible during formation of the neck). Changes in the crown shape (i.e., slower diameter formation) may be compensated by decreasing heater power earlier during crown formation (e.g., the heater power is reduced by at least about 1% and preferably at least about 2.5% in about the first 25% of crown diameter growth) to reduce the time at which the crown is formed.

### EXAMPLES

The processes of the present disclosure are further illustrated by the following Examples. These Examples should not be viewed in a limiting sense.

### Example 1: Oxygen Profile of Ingots with and without Crown Control

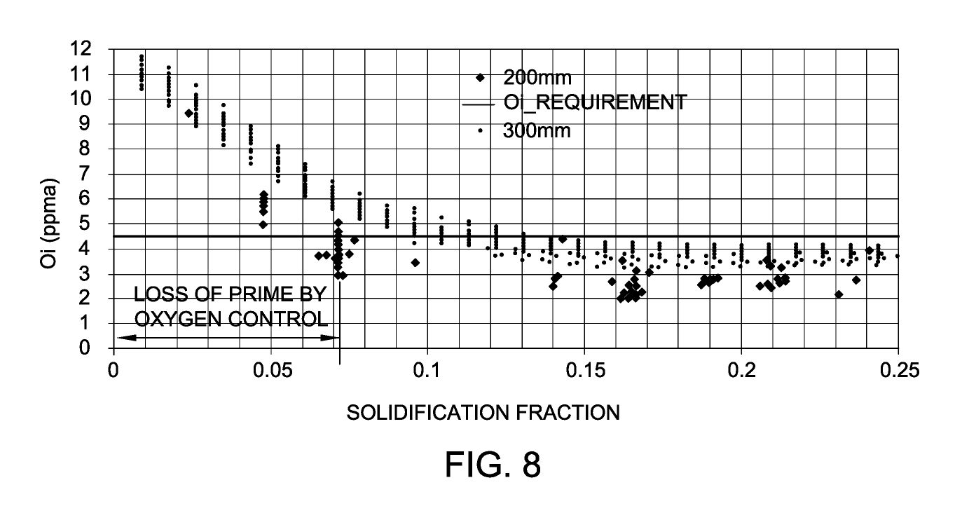

The oxygen profile in several 200 mm ingots and 300 mm ingots in which the crown was grown by conventional methods was determined by FT-IR. As shown in FIG. 8, the first 7% of the solidified 200 mm ingot fell outside of the most stringent customer specification of 4.4 ppma (i.e., was non-prime). About the first 12% of the 300 mm ingot contained oxygen at an amount above 4.4 ppma.

The crucible rotation during crown growth was controlled for 200 mm ingots to reduce oxygen content in a seed region of the constant diameter portion of the ingot (2100 mm length). FIG. 6 shows the normalized crucible rotation rate (relative to the rotation rate at the end of neck growth) in relation to the normalized crown length. The steady-state rotation over the last 25% of the crown growth was about 2.0 RPM.

FIG. 7 shows the normalized heater power during crown growth relative to the crown diameter. The power was reduced by about 6% relative to the power during neck growth over about the first 25% of crown diameter growth to compensate for slower diameter formation.

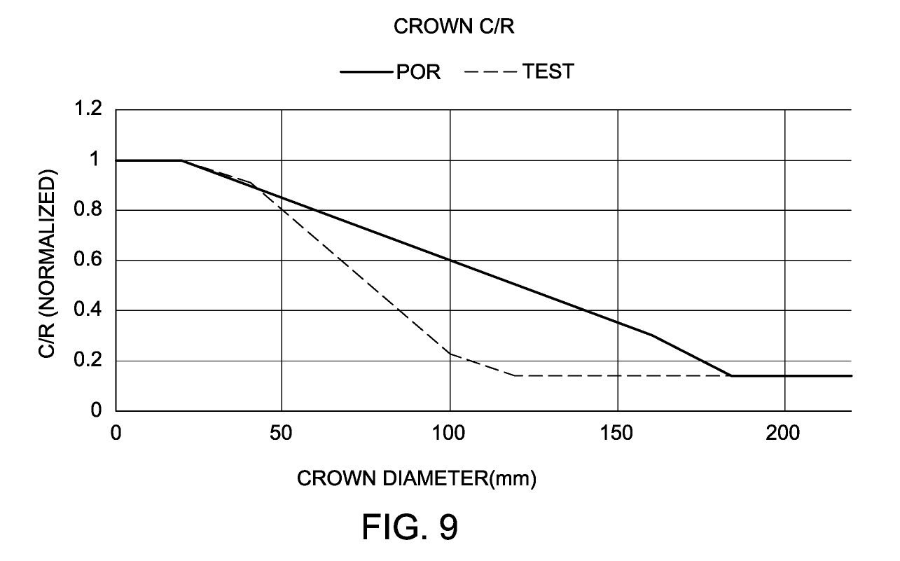

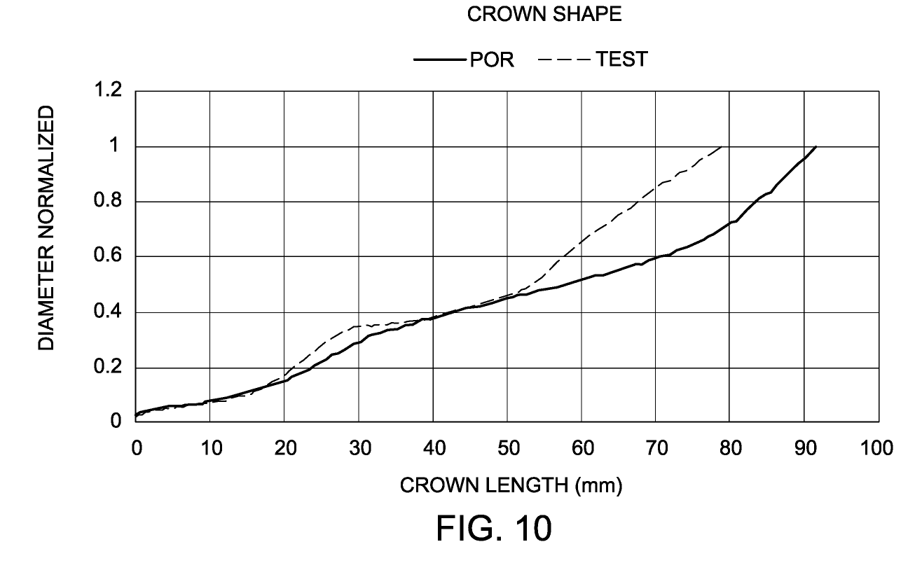

FIG. 9 shows the normalized crucible rotation (C/R) as it varied with crown diameter and FIG. 10 shows the crown shape (length vs normalized diameter). The data for the conventional process (POR) is also shown in FIGS. 6-7 and 9-10.

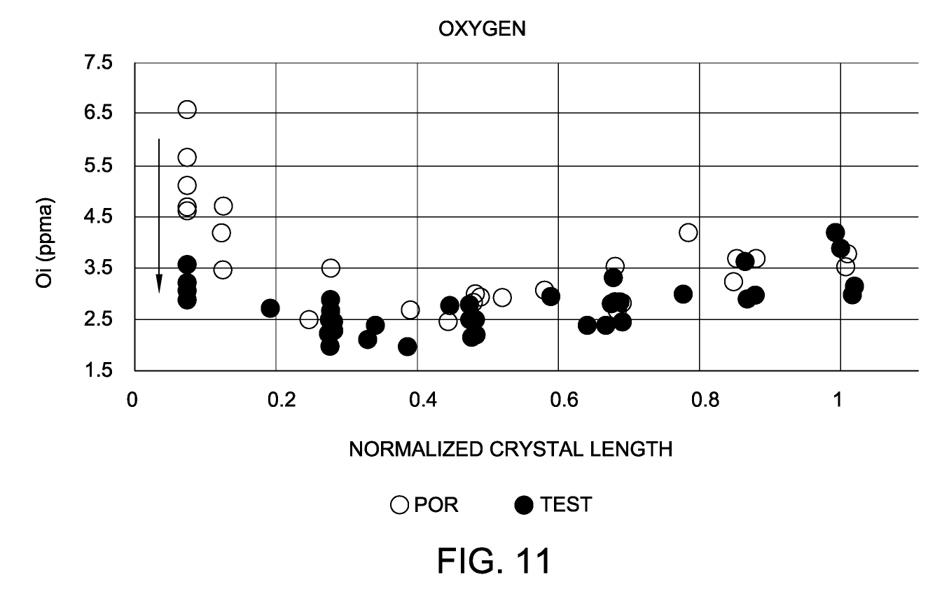

FIG. 11 shows the oxygen content in ingots in which the crown was controlled to reduce oxygen and the conventional method. As shown in FIG. 11, the new method in which the crown rotation was rapidly reduced lowered the oxygen content in the first 10% of the body relative to conventional methods and decreased the non-prime portion of the ingot.

### Example 2: Oxygen Dependence on Total Crown Time

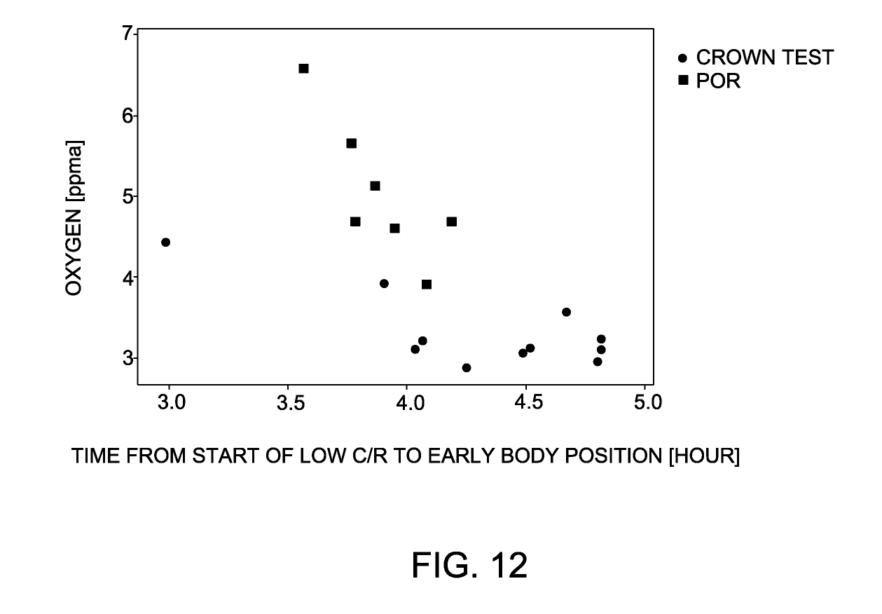

The ramp down condition of Example 1 increased the total time at which the crucible was rotated at a relatively low crucible rotation rate (e.g., less than 2.5 RPM such as at 2.0 RPM). FIG. 12 shows the oxygen content at the 150 mm position of the ingot (i.e., at about 7% of the ingot) as a function of total time from the start of low crucible rotation (about 2.0 RPM) during crown formation to formation of about the first 150 mm of the constant diameter portion of the ingot. As shown in FIG. 12, a longer period of low rotation during crown formation resulted in lower oxygen content at the 150 mm ingot position.

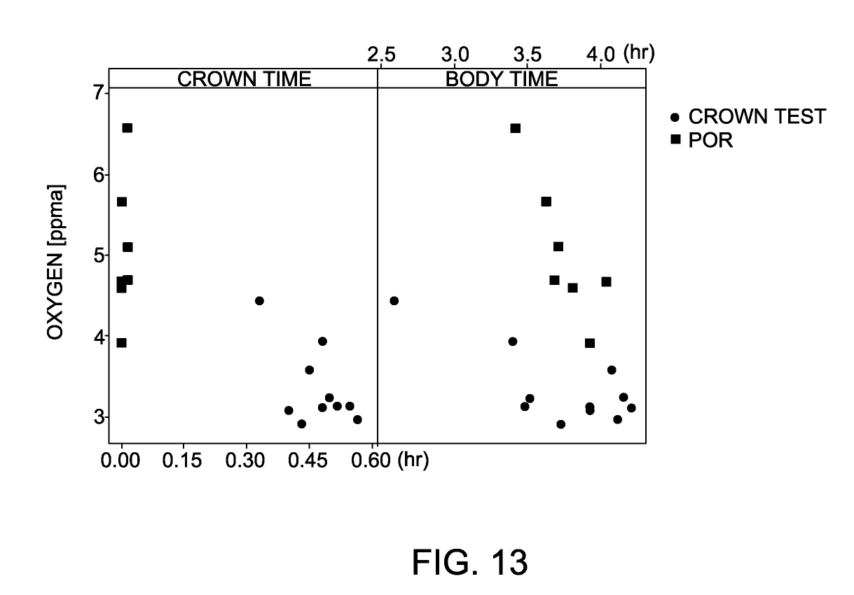

As shown in FIG. 12, even at similar process times, the lower crucible rotation rate resulted in lower interstitial oxygen (Oi) content. FIG. 13 divides the process time at low crucible rotation by the time to form the crown and the time to form the body. As shown in FIG. 13, the crown time at low C/R affected the Oi content while the impact of the low C/R time to form the body on the Oi content was negligible.

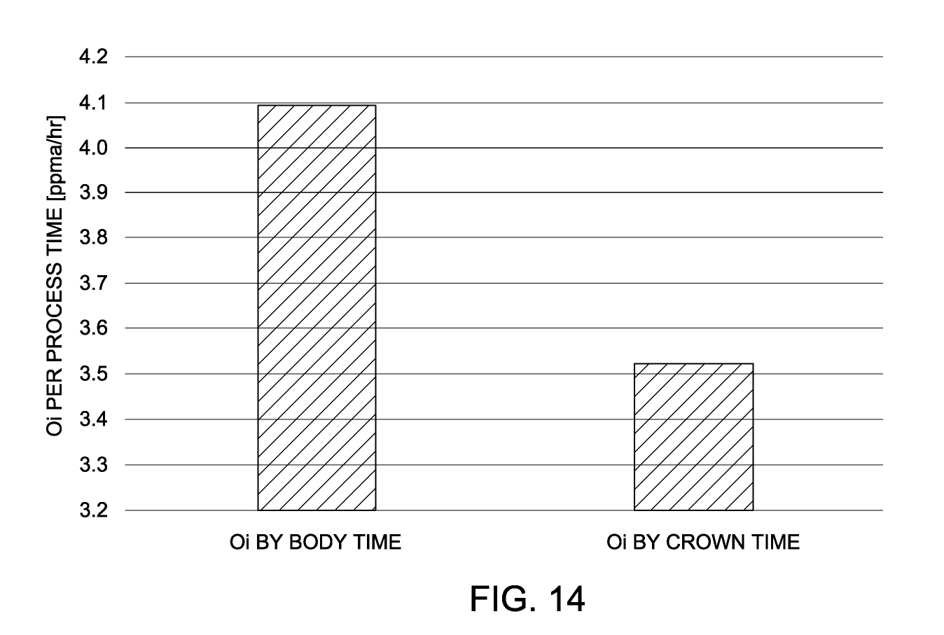

FIG. 14 shows the ppma reduction at 150 mm that may be attributed to low crucible rotation (e.g., less than 2.5 RPM) during crown growth and during body growth as a function of the period of time at the low crucible rotation. As shown in FIG. 14, lower crucible rotation during body growth impacts oxygen content more than during crown growth. However, lower crucible rotation during crown growth does not impact overall process time and productivity (through compensation by reduction of heater power) while low crucible rotation during body growth adds to overall process times.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for producing a single crystal silicon ingot from a silicon melt held within a crucible, the ingot having a constant diameter portion, a neck portion, a crown portion disposed between the neck portion and the constant diameter portion and tapering radially outward toward the constant diameter portion, and a terminal end, the method comprising:
contacting the melt with a seed crystal to initiate crystal growth;
pulling the seed crystal away from the melt to form the neck portion of the ingot;
forming a crown portion of the ingot, the crucible rotating while forming the crown at a crucible rotation rate;
forming the constant diameter portion of the ingot after the crown portion reaches a target diameter, the constant diameter portion having a seed region that extends from the crown portion and toward the terminal end of the ingot, the crucible rotation rate during formation of the crown portion being controlled to reduce the oxygen content in the seed region of the constant diameter portion of the ingot.

2. The method as set forth in claim 1 wherein the crucible rotation rate is controlled to be at or less than a threshold value during formation of at least a portion the crown portion.

3. The method as set forth in claim 1 further comprising rotating the crucible during formation of the neck portion, wherein controlling the crucible rotation rate during formation of the crown portion comprises maintaining the rate of rotation during formation of at least about the last 10% of the length of the crown to about 20% or less of the rate of rotation during formation of the neck.

4. The method as set forth in claim 1 further comprising rotating the crucible during formation of the neck portion, wherein controlling the crucible rotation rate during formation of the crown portion comprises maintaining the rate of rotation during formation of at least about the last 20% of the length of the crown to about 20% or less of the rate of rotation during formation of the neck.

5. The method as set forth in claim 1 wherein controlling the crucible rotation rate during formation of the crown portion comprises maintaining the rate of rotation during formation of at least about the last 10% or about the last 20% of the length of the crown to less than about 3.0 RPM.

6. The method as set forth in claim 1 further comprising rotating the crucible during formation of the neck portion, wherein controlling the crucible rotation rate during formation of the crown portion comprises reducing the rate of rotation by at least about 40% during formation of about the first 60% of the crown length relative to the rate of rotation of the crucible during formation of the neck.

7. The method as set forth in claim 1 further comprising rotating the crucible during formation of the neck portion, wherein controlling the crucible rotation rate during formation of the crown portion comprises reducing the rate of rotation by at least about 40% during formation of about the first 50% of the crown length relative to the rate of rotation of the crucible during formation of the neck.

8. The method as set forth in claim 1 further comprising rotating the crucible during formation of the neck portion, wherein controlling the crucible rotation rate during formation of the crown portion comprises reducing the rate of rotation by at least about 50% during formation of about the first 60% of the crown length relative to the rate of rotation of the crucible during formation of the neck.

9. The method as set forth in claim 1 further comprising rotating the crucible during formation of the neck portion, wherein controlling the crucible rotation rate during formation of the crown portion comprises reducing the rate of rotation by at least about 80% during formation of about the first 80% of the crown length relative to the rate of rotation of the crucible during formation of the neck.

10. The method as set forth in claim 1 wherein the melt is heated by a heating system, the method further comprising controlling the power supplied to the heating system during formation of the crown portion to compensate for reduced crown diameter caused by a lowered crucible rotation during crown growth.

11. The method as set forth in claim 10 wherein controlling the power supplied to the heating system comprises reducing the power during at least a portion of formation of the crown portion.

12. The method as set forth in claim 11 wherein the heater power is reduced by at least about 1% in about the first 25% of crown diameter growth.

13. The method as set forth in claim 11 wherein the heater power is reduced by at least about 5% during growth of about the first 50% of the crown diameter growth.

14. The method as set forth in claim 1 wherein the constant diameter portion of the ingot has a length and the seed region of the constant diameter portion has a length, the length of the seed region being less than about 10% of the length of the constant diameter portion.

15. The method as set forth in claim 14 wherein at least about 25% of the seed region of the constant diameter portion of the ingot has an oxygen concentration, the oxygen concentration being less than about 4.4 ppma.

16. An ingot produced by the method of claim 1.

17. A single crystal silicon ingot grown by a Czochralski method and comprising:
a constant diameter portion;
a neck portion;
a crown portion disposed between the neck portion and the constant diameter portion and tapering radially outward toward the constant diameter portion;
a terminal end, the constant diameter portion having a seed region that extends from the crown portion and toward the terminal end of the ingot and having a length of about 150 mm or less, a portion of the seed region having an oxygen concentration of about 4.4 ppma or less.

18. The single crystal silicon ingot as set forth in claim 17 wherein at least about 15% of the length of the seed region has an oxygen content of about 4.4 ppma or less.

19. The single crystal silicon ingot as set forth in claim 17 wherein at least about 25% of the length of the seed region has an oxygen content of about 4.4 ppma or less.

20. The single crystal silicon ingot as set forth in claim 17 wherein from about 5% to about 50% of the length of the seed region has an oxygen concentration of about 4.4 ppma or less.

21. The single crystal silicon ingot as set forth in claim 17 wherein the constant diameter portion of the ingot has a diameter of at least about 150 mm, about 200 mm, about 300 mm or about 450 mm.

22. A population of wafers sliced from the seed region of the constant diameter portion of the ingot of claim 17, wherein at least about 5% of the wafers have an oxygen concentration of about 4.4 ppma or less.

23. A population of wafers as set forth in claims 22 wherein from about 5% to about 50% of the wafers have an oxygen concentration of about 4.4 ppma or less.
